(19) United States
(12) Patent Application Publication
(10) Pub. No.: US 2005/0140360 A1
(43) Pub. Date: Jun. 30, 2005

(54) Process for determining a relative movement of two systems and a sensor therefor

(75) Inventors: Gyoergy Csikos, Locarno (CH); Daniele Sartori, Avegno (CH)

Correspondence Address: CROWELL & MORING LLP;INTELLECTUAL PROPERTY GROUP, P.O. BOX 14300, WASHINGTON, DC, 20044-4300, US

(73) Assignee: Emile Helayel, Montreal (CA)

(21) Appl. No.: 11/065,544

(22) Filed: Feb. 25, 2005

Related U.S. Application Data
(63) Continuation of application No. 10/454,595, filed on Jun. 5, 2003, now abandoned.
Application No. 10/454,595 is a continuation of application No. 09/715,059, filed on Nov. 20, 2000, now abandoned.

(51) Int. Cl. G01N 27/74; G01R 33/12; G01B 7/00; G01R 33/025

(52) U.S. Cl. 324/207.18; 324/207.15

(57) ABSTRACT

A method and apparatus for detecting relative movement of two system (S, S₂) by using electromagnets induction (B, v, i) on a sensor with a defined magnetic field (Bₘ) and compensating for the influence of an external interfering magnetic field (Bₛ) The magnetic field (Bₘ) is generated in at least two areas (M, M₂) with reversed polarity and a conductor arrangement is designed so that an addition induction effect (i, i₂) occurs on the conductor and the external interfering field (B₂) is corrected by the additive induction effect.

This application is a continuation of application Ser. No. 10/454,595, filed Jun. 5, 2003, which is a continuation of Ser. No. 09/715,059, filed Nov. 20, 2000.

### BACKGROUND AND SUMMARY OF THE INVENTION

The present invention relates to a method of detecting a relative movement of two systems.

The present invention is based on problems which occur when detecting seismic processes by means of sensors which utilize electromagnetic induction: It cannot be distinguished whether a recorded signal is generated on the basis of the seismic process and thus of the movement of an electric conductor with respect to an established magnetic measuring field or on the basis of a changing interfering magnetic field.

Seismic processes may also be accompanied by seismically caused electromagnetic fields. When sensors of the above-mentioned type are used, because of magnetic fields possibly accompanying seismic processes, measuring signals can be interpreted only with great uncertainty exclusively as being caused by movement, not taking into account additional non-seismically caused interfering magnetic fields. In addition, sensors for detecting seismically caused movement must be able to also detect extremely low-frequency signals, far below 10 Hz, even below 1 Hz, with a high sensitivity.

This results in the principal object on which the present invention is based, specifically to be able to detect the movement of seismic processes by means of utilizing induction and, in the process at least reducing the influence of interfering electromagnetic fields, whether they are caused seismically or otherwise. The following described solution on which the present invention is based while addressed to problems when detecting movements on the basis of seismic processes can easily be used for other movement sensor applications, particularly if similarly high demands are made on a suppression of interferences and sensitivity is demanded into the lowest frequency ranges.

The problem of interfering magnetic fields in the case of seismic sensors had not been considered to be very important.

The present invention achieves the above-mentioned object in that the influence of an external interfering magnetic field is counteracted by compensation.

Herein the term interfering magnetic field applies to any type of magnetic field except for the one which is established in a targeted manner for measuring purposes and which we want to call measuring magnetic field.

According to the invention, the influence of interfering magnetic fields which affects the measurements can be suppressed at the lowest frequency interference signals and with a sensitivity required during seismic measurements.

In a preferred embodiment of the method according to the invention, the defined measuring magnetic field, in at least two locally separated adjacent areas, is additively coupled with a conductor arrangement, but the interfering magnetic field is subtractively coupled. In this case, two magnetic fields with reversed polarity can be coupled to a given conductor arrangement, but are nevertheless added to one another in their induction effect because the conductor arrangement is correspondingly guided geometrically in the measuring fields. In contrast, an interfering magnetic field is essentially homogeneous in the area of the sensor, whereby, when the above-mentioned measures are taken, its induction effect is subtracted on the conductor arrangement.

Preferably, the measuring magnetic field is applied to the same extent in the two above-mentioned areas. However, this is not absolutely required.

In a preferred embodiment, the described conditions are implemented in that the defined measuring magnetic field, bound to one of the systems, is generated with at least two partial fields of different polarity which are radial with respect to an axis, and the conductor arrangement is constructed as an arrangement of at least two coils which are wound in opposite directions, are bound to the second system and whose coil axes are at least approximately coaxial with respect to the axis of the radial partial fields.

In addition to the compensation measures according to the invention, it is, however, easily possible to also provide shielding measures. If these are to be effective also at lowest-frequency signals, preferably at least the area of the sensor on which the induction is established is surrounded by means of an electrostatic shield. The shield is implemented, for example, by an electrically highly conductive coating or foil. The wall of a shield carrier housing, which is significantly thicker than the shield, is produced from electrically non-conducting, non-magnetic material, for example, of a plastic material.

Seismic movement sensors are known, in which case electromagnetic induction is utilized for recording movements. Reference is made, for example, to the sensors of the SM3-KV or SM3-KVE Types of the Russian Academy of Sciences, Design Bureau for Geophysical Instruments, or the sensor S-13 of Geotech Instruments Company, LLC.

These known seismic movement sensors are extremely suitable to be equipped by means of the measures according to the invention. In this case, a measuring magnetic field is bound to a journal bearing of a lever on the known sensor. In the above-mentioned bearing, the swivel pin of a lever is disposed, on which first a seismic mass and then a conductor arrangement is mounted which can be moved in the measuring magnetic field together with the lever. A spring arrangement also acts upon the lever, against the torque caused by the seismic mass. However, for the interfering magnetic field compensation according to the invention, the measuring magnetic field and the conductor arrangement are now constructed according to the invention.

The method according to the invention is particularly suitable for the detection of seismic processes and their analysis; in this case, particularly for finding hydrocarbon occurrences for obtaining information on hydrocarbon occurrences and/or on the extent of hydrocarbon occurrences.

This provides the possibility of separately recording movements caused by seismic processes and magnetic fields caused by seismic processes and of analyzing them as separate components of one and the same process.

Other objects, advantages and novel features of the present invention will become apparent from the following detailed description of the invention when considered in conjunction with the accompanying drawings.

### BRIEF DESCRIPTION OF THE DRAWINGS

FIG. 1 is a schematic and perspective view of the induction effect of a magnetic field on a movable conductor, as a basis for understanding the present invention;

FIG. 2 is a representation analogous to FIG. 1 of the basic implementation according to the invention of a measuring magnetic field and a conductor arrangement moving therein;

FIG. 3 is a longitudinal sectional view of a preferred embodiment of a sensor operating according to the method of the invention;

FIG. 4 is a schematic view of a seismic sensor of the invention constructed on the basis of a known seismic sensor;

FIG. 5a is a view of the signal in the 50 Hz interfering field environment received by means of a conventional, not interfering-field-compensated inductive measuring head, in the time range;

FIG. 5b is a view of the signal according to FIG. 5a in the frequency range;

FIG. 6a is a view, analogous to the view of FIG. 5a, of the measuring signal in the same environment with an interfering-field-compensated sensor constructed according to the invention;

FIG. 6b is a view of the signal according to FIG. 6a in the frequency range; and

FIG. 7 is a view of the amplitude characteristics and the phase frequency characteristics of the sensor of the invention constructed according to FIG. 4 with an installed operating point control and with phase frequency characteristics compensation.

### DETAILED DESCRIPTION OF THE PREFERRED EMBODIMENTS

The relative movement of a system S₁ with respect to a system S₂ is to be detected. For the respective utilization of the induction, a measuring magnetic field Bₘ is generated on the one system S₁. When, in this induction field Bₘ, a conductor 3, which extends perpendicular to the lines of flux of the measuring magnetic field Bₘ, is moved at the speed v in the illustrated direction, a voltage is induced in the conductor 3.

Thus, it now becomes possible to measure the speed v in the indicated direction by measuring the induced voltage on the conductor 3 of the conductor arrangement. In contrast, a position determination of the conductor 3 in the static field Bₘ, which is assumed to be uniform, is not possible by means of induction.

When a time-variable interfering field Bₛ(t) exists in the field-filled space area M, because of its time variation, independently of whether or not system S₂ is moved with the conductor 3, this interfering field Bₛ(t) causes a voltage in the conductor 3. For this reason, it cannot be discriminated on an electric signal tapped at the conductor 3 whether it is generated only because of a relative movement of the systems S₁, S₂, only because of the time variation of the interfering field Bₛ or because of a combination of both causes.

Thus when, by means of induction, the movement of a seismic process is to be monitored, the measuring result does not indicate with certainty whether a time-variable interfering field and/or a movement was detected.

However, specifically when examining seismic processes, it is very important to separately record movements and seismically caused electromagnetic fields, apart from the fact that magnetic fields which are not seismically caused and which also enter in Bₛ, are never of interest here.

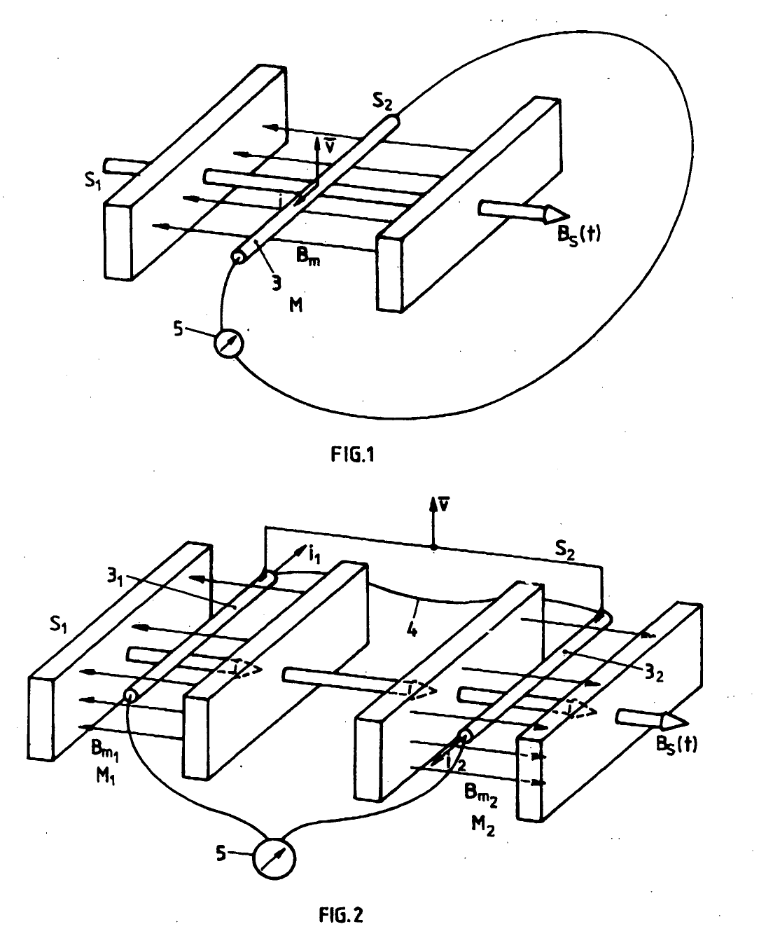

Based on the problems indicated in conjunction with FIG. 1, FIG. 2 shows the principle of the solution according to the invention. Accordingly, the measuring magnetic field Bₘ is applied in at least two mutually separated areas of system S₁; according to FIG. 2, in area M₁ as partial magnetic field Bₘ₁ and in area M₂ as partial magnetic field Bₘ₂. With respect to the movement direction of system S₂, corresponding to \overline{v}, and the alignment of the respective conductors 3₁ and 3₂ in the two areas M₁ and M₂, the partial magnetic fields Bₘ₁ and Bₘ₂ are reversely polarized. As a result of the corresponding wiring of the conductors 3₁ and 3₂, as schematically illustrated at reference number 4, they are connected in series such that the induction voltages occurring during a joint system movement \overline{v} are added in the conductors 3₁ and 3₂. A measuring instrument is schematically illustrated by means of reference number 5.

When, analogous to FIG. 1, the time-variable interfering magnetic field Bₛ(t) is considered, FIG. 2 illustrates that the field uniformly fills the two adjacent areas M₁ and M₂ and, as a result, the resulting induction voltages are also compensated in the conductors 3₁ and 3₂.

It is not absolutely necessary that the induction effect is doubled in spaces M₁ and M₂ of the measuring magnetic field Bₘ, but it is important that the induction effect in both above-mentioned spaces, if possible, is identical with respect to the interfering magnetic field Bₛ, so that an interfering signal compensation takes place which is as complete as possible.

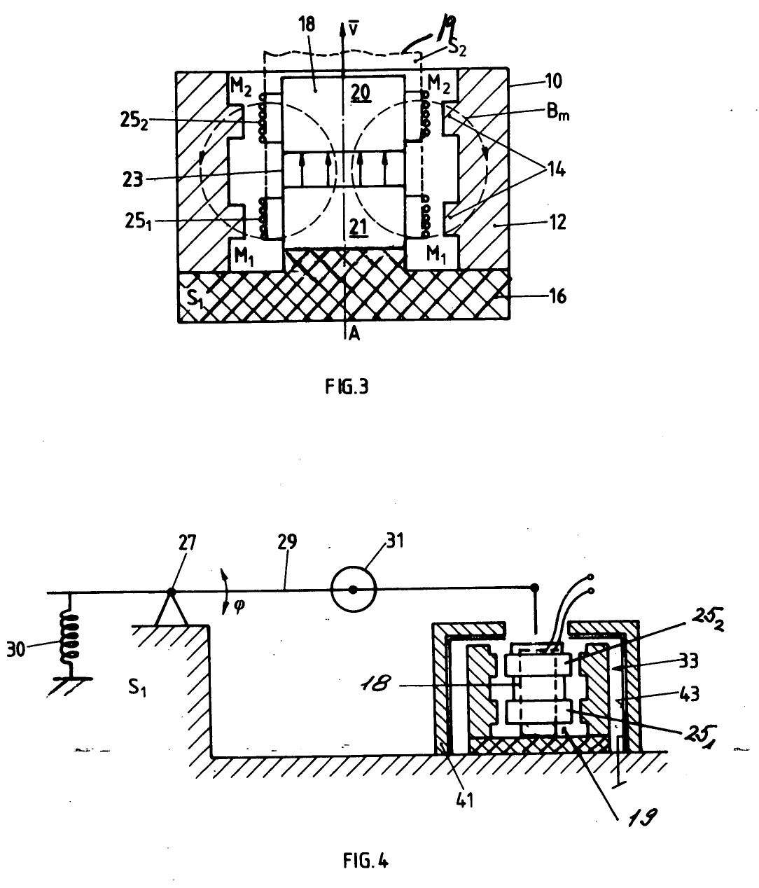

FIG. 3 is a schematic view of a preferred embodiment of a sensor according to the invention. A symmetrical annular-gap magnet 10 comprises a pole section 12 which is cylindrical with respect to an axis A, optionally with two inward jutting pole flanges 14 coaxial with respect to the axis A. Pole section 12 is constructed of a magnetically soft material, for example, made of iron or steel.

On the base side, pole section 12 is closed off by a base plate 16 made of a non-magnetic material, for example, of a plastic material or of stainless steel, which coaxially to the axis A in the pole section 12 carries a core 18, with magnetically soft pole parts 20 and 21 as well as a magnet arrangement 23 disposed in-between, preferably constructed as a strong permanent magnet, such as a neodymium magnet. By means of this arrangement, a radial measuring magnetic field Bₘ is formed. Naturally, it is also easily possible to use, instead of or in addition to the permanent magnet 23, for example, also in or on the wall of the pole section 12, additional magnet arrangements and always permanent and/or electromagnets.

On a support 19 of the system S₂ illustrated in FIG. 3 by a broken line, coils 25₂ and 25₁, which form conductor arrangements according to FIG. 2, are mounted such that, together with the system S₂, the coils can be moved in a non contact manner over the core 18 and in the radial magnetic partial fields in areas M₁ and M₂ respectively.

Analogous to the representation of FIG. 2, the coils 25₁ and 25₂ are series-connected such that the induction voltages resulting from the system movement v are added up. Between the magnetically soft core parts 20 and 21, on the one hand, and the pole section 12, on the other hand, two cylindrical air gaps, which are coaxial with respect to the axis A, are formed corresponding to the areas M₁ and M₂ of FIG. 2. These are filled with the radial measuring magnetic fields of reversed polarity which act upon the coil arrangements 25 displaceable in the air gaps. Interfering magnetic fields fill both air gaps in a uniform manner, whereby, corresponding to the explanations with respect to FIG. 2, their induction effect on the coils 25₁ and 25₂ is compensated.

Although the approach discussed here is particularly suitable for the interfering-field-compensated recording of movements which originate in seismic processes, correspondingly constructed movement sensors can also be used for the detection of relative movements between systems which have different causes.

FIG. 4 schematically shows a particularly preferred embodiment of a seismic movement sensor constructed, on the one hand, of the basic mechanism of the known sensor SM3-KV or SM3-KVE of the initially mentioned firm and, on the other hand, supplemented by the measures according to the invention, as explained by means of FIG. 3. From a physical point of view, this is a pendulum arrangement.

The known seismic movement sensor comprises a lever 29 with a large seismic mass 31 disposed in a swivel bearing 27 on a support system S₁. At the end of the lever 29, the support 19 of the inductively acting measuring head 33, which is now constructed according to the invention, is mounted, as explained according to FIG. 3. A spring arrangement 30 acts against the torque of the mass 31 on the lever 29.

The calibrating and adjusting measures provided on the known sensor are not illustrated in FIG. 4. As shown in FIG. 3, it is also important in the case of the approach according to the invention that, for utilizing a linear movement/signal transmission range which is as large as possible, in the inoperative condition, system S₂ is returned with respect to system S₁ into a defined operating point position which is preferably symmetrical with respect to areas M₁ and M₂. For this reason, an operating point control is provided on the movement sensor in a known manner (not shown).

In order to minimize the influence of electric interfering fields in all embodiments of the method of the invention, as schematically illustrated in FIG. 4, the measuring head, with the induction-effective space areas, is installed in a housing 41 whose wall material has poor conduction. A plastic material or stainless steel can, for example, be used as the wall material. The interior wall of the housing 41 is covered or coated with a thin shield 43 of an electrically well conducting material, such as copper, or with a conducting lacquer. The shield 43 is preferably applied to a measuring reference potential. This prevents a capacitive interference of electric fields.

A seismic movement sensor of the SM3-KV Type of the initially mentioned firm, as schematically illustrated in FIG. 4, but with a conventional, inductively acting measuring head, was set up in a 50 Hz-interfering-field-contaminated environment and was mechanically blocked and, on the single provided induction coil, the resulting signal was recorded in an intensified manner. In the time range, the signal illustrated in FIG. 5a is obtained; in the frequency range, the FIG. 5b signal is obtained. The 50 Hz interfering field as well as another interfering field at approximately 16⅔ Hz are clearly visible.

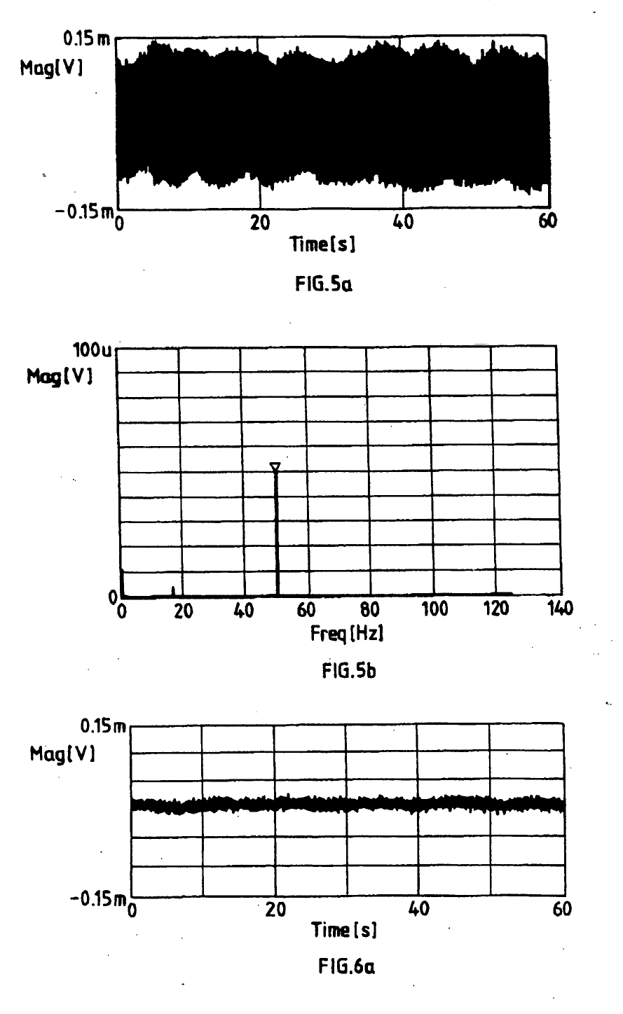

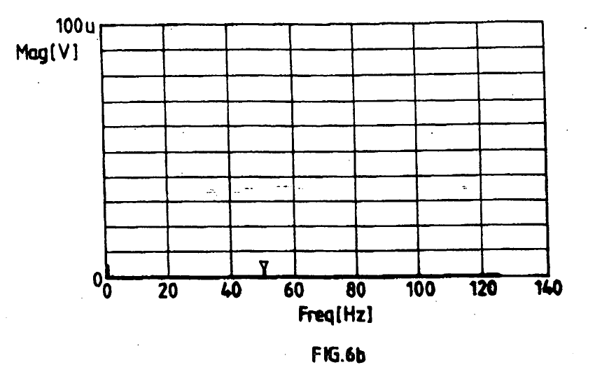

When a retooling took place to the measuring head of the invention according to FIG. 4 or FIG. 3, while the conditions were otherwise identical, in the time range, the signal according to FIG. 6a was obtained, and in the frequency range, the signal according to FIG. 6b was obtained.

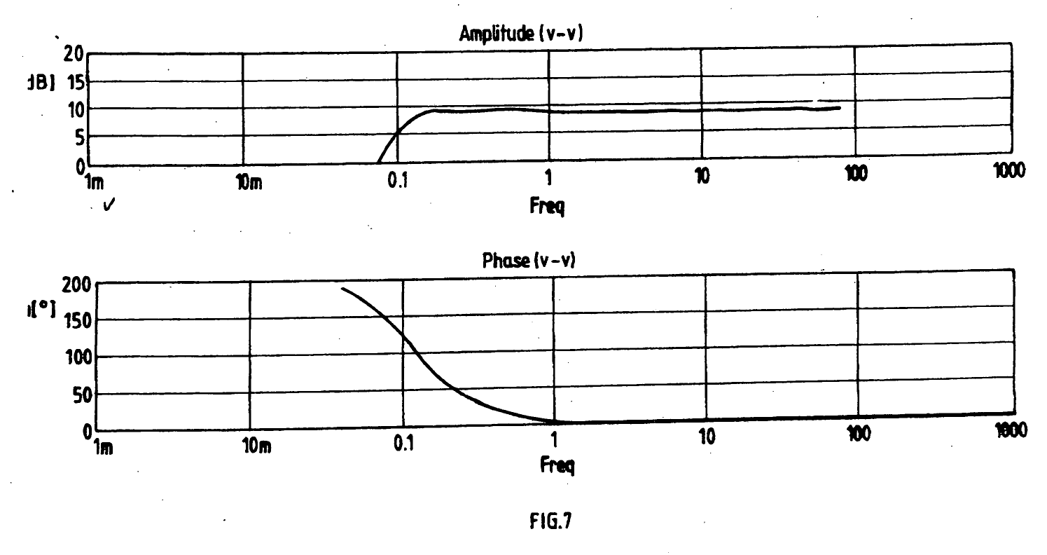

The influence of the compensation according to the invention is extremely clear with an interfering signal reduction by a factor of approximately 25. FIG. 7 shows additional amplitude and phase frequency characteristics of the movement sensor according to FIG. 4 with an operating point control. In this case, the phase frequency characteristics were optimized by a correction filter on the amplifier circuit connected behind the measuring head 33 according to FIG. 4.

By means of the method according to the invention, it now becomes possible seismic processes.

Additionally, because magnetic field sensors are known, it now becomes possible to separately record both components of seismic processes, specifically the resulting movements and the resulting magnetic fields, while these magnetic fields do not interfere with the recording of the movements. This therefore results in a new dimension of the analysis of seismic processes, and thus for finding underground hydrocarbon occurrences and/or for determining the extent of such occurrences.

In general, the suggested approach provides the possibility of inductively detecting movements between systems to the lowest frequencies, while an interfering field which may be present at the measuring site will not interfere with the measurement.

The foregoing disclosure has been set forth merely to illustrate the invention and is not intended to be limiting. Since modifications of the disclosed embodiments incorporating the spirit and substance of the invention may occur to persons skilled in the art, the invention should be construed to include everything within the scope of the appended claims and equivalents thereof.

1-17. (canceled)

18. A method of detecting relative movement of two systems (S₁, S₂) in an interfering magnetic field comprising:
generating a defined measuring magnetic field (Bₘ) acting on one of said two systems; and
compensating for an influence of said external interfering magnetic field (Bₛ).

19. The method according to claim 18, wherein the defined measuring magnetic field (Bₘ) is provided in at least two locally separated adjacent areas (M₁, M₂), each with a same field intensity but with an opposite polarity, and said defined measuring is additively applied to a conductor arrangement and simultaneously the external interfering magnetic field is subtractively applied to the conductor arrangement.

20. The method according to claim 18, wherein the defined measuring magnetic field (Bₘ) is generated with at least two partial fields of reversed polarity which are radial with respect to a common axis, and a conductor arrangement (25₁, 25₂) is constructed as an arrangement of two coils which are wound in opposite directions and whose coil axes are at least approximately coaxial with respect to the above-mentioned axis and which are bound to the second system (S₂).

21. Method according to claim 18, wherein an area of the sensor on which the induction is established is electrically shielded.

22. The method according to claim 18 for detecting seismically caused movements, wherein the measuring magnetic field (Bₘ) is bound to a journal bearing of a sprung lever, wherein a swivelling axis of the lever is disposed in said journal bearing and wherein, a seismic mass is first mounted on said journal bearing and then a conductor arrangement which is movable with the lever in the measuring magnetic field (Bₘ) is mounted on said journal bearing.

23. A sensor arrangement for detecting a relative movement of a first and second system (S₁, S₂), positioned in an external interfering magnetic field, said arrangement comprising:
means for generating a measuring magnetic field (Bₘ); and
a movable conductor arrangement fixed on the second system (S₂) said conductor arrangement positioned in the measuring magnetic field, wherein the measuring magnetic field (Bₘ) is generated in at least two areas (M₁, M₂). with reversed polarity, and wherein the conductor arrangement is designed such that, as a result of the measuring magnetic field (Bₘ) in each of said at least two areas (M₁, M₂), an additive induction effect (i₁, i₂) occurs on the conductor arrangement, whereby an effect of said external interfering magnetic field (Bₛ) acting uniformly over the at least two areas (M₁, M₂) is compensated.

24. The sensor arrangement according to claim 23, wherein the measuring magnetic field (Bₘ) in the at least two areas (M₁, M₂) has substantially a constant field intensity, and the conductor arrangement in the at least two areas (M₁, M₂) has essentially identical series-connected conductors.

25. The sensor arrangement according to claim 24, wherein the measuring magnetic field (Bₘ) is essentially radial with respect to an axis and has reversed polarity in the two areas.

26. The sensor arrangement according to claim 25, wherein in the conductor arrangement comprises two coils wound in opposite directions, whose axes are essentially coaxial with respect to the axis of the measuring magnetic field and which are moved in the measuring magnetic field.

27. The sensor arrangement according to claim 26, wherein an annular-gap magnet arrangement is provided which generates the measuring magnetic field (Bₘ).

28. The sensor arrangement according to claim 27, wherein a core of the annular-gap magnet arrangement comprises an axially magnetized magnet.

29. The sensor arrangement according to claim 28, wherein the at least two areas are electrically shielded.

30. The sensor arrangement constructed as a seismic sensor according to claim 29, wherein a lever is provided which is elastically swivellably disposed and on which, progressing from the swivel bearing along the lever, first a seismic mass is fastened and then a conductor arrangement.

31. The sensor arrangement according to claim 30, wherein the relative movement is caused by seismic processes for at least one of finding underground hydrocarbon deposits and for determining an extent of said deposits.
